(19) United States
(12) Patent Application Publication
(10) Pub. No.: US 2025/0366073 A1
(43) Pub. Date: Nov. 27, 2025

(54) FERROELECTRIC TRANSISTOR AND METHOD OF OPERATING THE SAME

(71) Applicant: POSTECH RESEARCH AND BUSINESS DEVELOPMENT FOUNDATION, Pohang-si (KR)

(72) Inventors: Jang Sik LEE, Pohang-si (KR); Ik Jyae KIM, Pohang-si (KR)

(21) Appl. No.: 19/216,978

(22) Filed: May 23, 2025

(30) Foreign Application Priority Data
May 24, 2024 (KR) 10-2024-0067579

(51) Int. Cl. H10D 30/69; G11C 11/22; H10B 51/20; H10D 64/68

(52) U.S. Cl. CPC H10D 30/701; G11C 11/2273; G11C 11/2275; G11C 11/2277; G11C 11/2297; H10B 51/20; H10D 64/689

(57) ABSTRACT

A ferroelectric transistor according to an aspect of the present disclosure includes a substrate, a control gate electrode layer formed on the substrate, a first ferroelectric layer on the control gate electrode layer, an inner electrode layer on the first ferroelectric layer, a second ferroelectric layer on the inner electrode layer, and a semiconductor channel layer on the second ferroelectric layer, wherein a ratio of a second capacitance of a second stacked structure of the inner electrode layer, the second ferroelectric layer, and the semiconductor channel layer to a first capacitance of a first stacked structure of the control gate electrode layer, the first ferroelectric layer, and the inner electrode layer is 5 or more.

### CROSS-REFERENCE TO RELATED APPLICATIONS

This application claims priority from Korean Patent Application No. 10-2024-0067579, filed on May 24, 2024, in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device and more specifically to a ferroelectric transistor.

The present disclosure relates to the Next-generation Intelligence semiconductor R&D Program through the National Research Foundation of Korea (NRF) funded by the Korea government (MSIT) (RS-2023-00258227).

### BACKGROUND

Electronic products require high-speed data processing and high-capacity data processing, even though their volume is getting smaller and smaller. Accordingly, there is a need to increase their performance and degree of integration while reducing the volume of semiconductor devices used in such electronic products.

Accordingly, a next-generation memory device is being studied to overcome limitations of a conventional memory device. For example, a ferroelectric transistor or a ferroelectric memory device is attracting attention as one of such a next-generation memory device due to a single transistor operation and fast operation speed.

However, in a case of a conventional ferroelectric transistor, it is difficult to implement multi-level characteristics because a memory window is defined by characteristics of a ferroelectric layer. Therefore, an optimal method is needed to expand the memory window of the ferroelectric transistor.

Furthermore, in a case of a conventional ferroelectric memory device, it is difficult to implement the multi-level characteristics because the memory window is defined by the characteristics of the ferroelectric layer. For example, in order to implement the multi-level characteristics using a conventional ferroelectric memory device, a method of gradually increasing a voltage magnitude or time applied, such as an incremental step pulse programming (ISPP) method, may be used. However, in a case of a ferroelectric, it is difficult to implement linear multi-level characteristics because a polarization state changes rapidly in a coercive electric field.

### SUMMARY

### Technical Problem

The present disclosure is designed to solve the above-mentioned problem, and a technical object of the present disclosure is directed to providing a ferroelectric transistor capable of expanding a memory window. Another technical object of the present disclosure is to provide a ferroelectric memory device capable of implementing linear multi-level characteristics and an operating method thereof. However, these problems are exemplary and the scope of the present disclosure is not limited thereto.

### Technical Solution

A ferroelectric transistor according to an aspect of the present disclosure for solving the above problem may include a substrate, a control gate electrode layer on the substrate, a first ferroelectric layer on the control gate electrode layer, an inner electrode layer on the first ferroelectric layer, a second ferroelectric layer on the inner electrode layer, and a semiconductor channel layer on the second ferroelectric layer, wherein a ratio of a second capacitance of a second stacked structure of the inner electrode layer, the second ferroelectric layer, and the semiconductor channel layer to a first capacitance of a first stacked structure of the control gate electrode layer, the first ferroelectric layer, and the inner electrode layer is 5 or more.

According to the ferroelectric transistor, in order to have a memory window equal to or greater than 7 V, the ratio of the second capacitance to the first capacitance may be 6 or more.

According to the ferroelectric transistor, in order to have a memory window equal to or greater than 10 V, the ratio of the second capacitance to the first capacitance may be 10 or more.

According to the ferroelectric transistor, a ratio of a second area where an upper surface of the inner electrode layer contacts with the second ferroelectric layer in the second stacked structure to a first area where an upper surface of the control gate electrode layer contacts with the first ferroelectric layer in the first stacked structure may be 1, and in order to have a memory window equal to or greater than 7 V, a ratio of a first thickness of the first ferroelectric layer to a second thickness of the second ferroelectric layer may be 6 or more.

According to the ferroelectric transistor, in order to have a memory window equal to or greater than 8 V, a ratio of a second area where an upper surface of the inner electrode layer contacts with the second ferroelectric layer in the second stacked structure to a first area where an upper surface of the control gate electrode layer contacts with the first ferroelectric layer in the first stacked structure may be 5 or more.

According to the ferroelectric transistor, the first ferroelectric layer and the second ferroelectric layer may be formed of a same material.

A ferroelectric transistor according to an aspect of the present disclosure for solving the above problem may include a substrate, a semiconductor channel layer having a cylindrical shape extended vertically on the substrate, an inner ferroelectric layer surrounding an outer circumferential surface of the semiconductor channel layer once, an inner electrode layer surrounding an outer circumferential surface of the inner ferroelectric layer once, an outer ferroelectric layer surrounding an outer circumferential surface of the inner electrode layer once, and a control gate electrode layer surrounding an outer circumferential surface of the outer ferroelectric layer once, wherein a ratio of a second capacitance of a second stacked structure of the inner electrode layer, the inner ferroelectric layer, and the semiconductor channel layer to a first capacitance of a first stacked structure of the control gate electrode layer, the outer ferroelectric layer, and the inner electrode layer may be 5 or more.

According to the ferroelectric transistor, in order to have a memory window equal to or greater than 7 V, the ratio of the second capacitance to the first capacitance may be 6 or more.

According to the ferroelectric transistor, in order to adjust the ratio of the second capacitance to the first capacitance, a thickness of the inner ferroelectric layer may be adjusted.

According to the ferroelectric transistor, the inner electrode layer may have a cylindrical shape with a circumferential groove recessed outward, the outer ferroelectric layer may be formed inside the groove of the inner electrode layer, and the control gate electrode layer may be formed outside of the outer ferroelectric layer to fill the groove.

According to the ferroelectric transistor, the transistor may include a current control device connected to the inner electrode layer, and a multi-level operation may be possible by controlling a displacement current through the inner electrode layer using the current control device and controlling a polarization level of the ferroelectric layer as multi-level.

According to the ferroelectric transistor, the current control device may include a bipolar junction transistor and control the displacement current through the inner electrode layer by changing a current flowing into a base terminal of the bipolar junction transistor.

According to the ferroelectric transistor, the base terminal may be connected to a base power supply unit through a resistor, and a change in a current flowing into the base terminal may be performed by changing an applied voltage of the base power supply unit.

According to another aspect of the present disclosure for solving the technical problems, a multi-level operating method of a ferroelectric transistor including a semiconductor channel layer, a control gate electrode layer, an inner electrode layer between the semiconductor channel layer and the control gate electrode layer, and a ferroelectric layer interposed at least between the control gate electrode layer and the inner electrode layer, the method including programming of applying a program voltage to the control gate electrode layer, controlling of a displacement current of controlling a polarization level of the ferroelectric layer as multi-level by controlling the displacement current through the inner electrode layer, and verifying of applying a read voltage to the control gate electrode layer may be provided.

According to the multi-level operating method of a ferroelectric transistor, in the controlling of the displacement current, as the displacement current is increased, a threshold voltage of a ferroelectric memory device may be decreased.

According to the multi-level operating method of a ferroelectric transistor, the ferroelectric memory device may include a current control device connected between the inner electrode and the ground and control the displacement current through the inner electrode layer using the current control device.

According to the multi-level operating method of a ferroelectric transistor, the current control device may include a bipolar junction transistor and control the displacement current through the inner electrode layer by changing a current flowing into a base terminal of the bipolar junction transistor in the controlling of the displacement current.

According to the multi-level operating method of a ferroelectric transistor, the base terminal may be connected to a base power supply unit through a resistor, and a change in a current flowing into the base terminal may be performed by changing an applied voltage of the base power supply unit in the controlling of the displacement current.

According to the multi-level operating method of a ferroelectric transistor, the programming, the controlling of the displacement current, and the verifying may be repeated multiple times while changing the displacement current so as to change the polarization level of the ferroelectric layer.

According to the multi-level operating method of a ferroelectric transistor, erasing of applying an erase voltage to the control gate electrode layer may be performed before repeating the programming after the verifying.

### Advantageous Effects

According to a ferroelectric transistor according to some embodiments of the present disclosure as described above, performance and stability thereof can be improved by expanding a memory window. In addition, a ferroelectric memory device and a manufacturing method thereof according to some embodiments of the present disclosure can improve operating performance and operating reliability and increase memory capacity.

Of course, these effects are exemplary, and the scope of the present disclosure is not limited by these effects.

### BRIEF DESCRIPTION OF THE DRAWINGS

FIG. 1 is a schematic cross-sectional view showing a ferroelectric transistor according to an embodiment of the present disclosure.

FIG. 2 is a schematic cross-sectional view showing a ferroelectric transistor according to another embodiment of the present disclosure.

FIG. 3 is a schematic cross-sectional view showing a portion of the ferroelectric transistor in FIG. 2.

FIG. 4 is a schematic cross-sectional view showing a ferroelectric transistor according to still another embodiment of the present disclosure.

FIG. 5 is a schematic cross-sectional view showing a ferroelectric transistor according to yet another embodiment of the present disclosure.

FIG. 6 is a schematic cross-sectional view showing a portion of the ferroelectric transistor in FIG. 5.

FIGS. 7 to 11 are graphs showing operating characteristics of a ferroelectric transistor according to embodiments of the present disclosure.

FIG. 12 is a schematic cross-sectional view showing a ferroelectric memory device according to some embodiments of the present disclosure.

FIG. 13 is a schematic cross-sectional view showing a ferroelectric memory device according to some embodiments of the present disclosure.

FIG. 14 is an equivalent circuit diagram of the ferroelectric memory device in FIGS. 12 and 13.

FIG. 15 is a schematic perspective view showing a ferroelectric memory device according to some embodiments of the present disclosure.

FIG. 16 is an equivalent circuit diagram of the ferroelectric memory device in FIG. 15.

FIG. 17 is a flowchart showing a multi-level operating method of a ferroelectric memory device according to some embodiments of the present disclosure.

FIG. 18 is a time chart showing a multi-level operating method of a ferroelectric memory device according to some embodiments of the present disclosure.

FIGS. 19 to 21 are graphs showing multi-level operation characteristics of a ferroelectric memory device according to some embodiments of the present disclosure.

### DETAILED DESCRIPTION OF THE EMBODIMENTS

Hereinafter, various embodiments of the present disclosure will be described in detail with reference to the attached drawings. However, the present disclosure is not limited to the embodiments disclosed below, but may be implemented in various different forms. The following embodiments are provided to ensure that the disclosure of the present disclosure is complete, and to fully inform those skilled in the art of the scope of the disclosure. In addition, for convenience of explanation, at least some components in the drawings may be exaggerated or reduced in size. In the drawings, same symbols refer to same elements.

Unless otherwise defined, all terms used herein have the same meaning as commonly understood by those skilled in the art. In the drawings, the sizes of layers and regions are exaggerated for illustrative purposes and are therefore provided to describe the general structures of the present disclosure.

Same reference numerals refer to same components. It will be understood that when a configuration such as a layer, region, or substrate, is referred to as being on another configuration, it may be directly on top of the other configuration, or other intervening configurations may also be present. On the other hand, when a configuration is referred to as being “directly on” another configuration, it is understood that there are no intervening configurations.

FIG. 1 is a schematic cross-sectional view showing a ferroelectric transistor 100 according to an embodiment of the present disclosure.

Referring to FIG. 1, the ferroelectric transistor 100 may include a substrate 105, a control gate electrode layer 110, first and second ferroelectric layers 120a, 120b, an inner electrode layer 130, and a semiconductor channel layer 140.

The ferroelectric transistor 100 may also be referred to as a ferroelectric field effect transistor (ferroelectric FET, FeFET) or a ferroelectric memory device. However, the ferroelectric transistor 100 may be distinguished from the ferroelectric memory device that stores data using a capacitor, in that the ferroelectric transistor 100 has memory characteristics by using a polarization phenomenon of a ferroelectric material and does not require a separate capacitor.

In the ferroelectric transistor 100, the control gate electrode layer 110 and the semiconductor channel layer 140 may be provided on the substrate 105, and the inner electrode layer 130 may be provided between the semiconductor channel layer 140 and the control gate electrode layer 110. The first ferroelectric layer 120a may be interposed at least between the control gate electrode layer 110 and the inner electrode layer 130, and the second ferroelectric layer 120b may be interposed between the inner electrode layer 130 and the semiconductor channel layer 140.

More specifically, the substrate 105 may include a semiconductor material such as silicon, germanium, or silicon-germanium. For example, the substrate 105 may be provided in a form of a semiconductor wafer. Furthermore, the substrate 105 may further include an insulating layer on the semiconductor wafer for insulation from an upper structure. As another example, when a thin film transistor structure is formed on the substrate 105, the substrate 105 may be formed of an insulating material, and when a transparent material is required, the substrate 105 may be formed of glass or the like.

The control gate electrode layer 110 may be disposed on the substrate 105, and the first ferroelectric layer 120a may be disposed on the control gate electrode layer 110. Furthermore, the inner electrode layer 130 may be disposed on the first ferroelectric layer 120a, the second ferroelectric layer 120b may be disposed on the inner electrode layer 130, and the semiconductor channel layer 140 may be disposed on the second ferroelectric layer 120b.

In some embodiments, the first and second ferroelectric layers 120a, 120b are layers capable of storing data using a polarization phenomenon and may include a high dielectric material, for example, a hafnium-based oxide. For example, the first and second ferroelectric layers 120a, 120b may include a hafnium oxide to which at least one of zirconium (Zr), aluminum (Al), silicon (Si), yttrium (Y), gadolinium (Gd), and lanthanum (La) is added, or a stacked structure thereof. Optionally, the first and second ferroelectric layers 120a, 120b may be doped with an impurity. In addition, the first and second ferroelectric layers 120a, 120b may be formed of a same material.

The semiconductor channel layer 140 may include a semiconductor material such as silicon, germanium, silicon-germanium, or oxide semiconductor. For example, the semiconductor channel layer 140 may include an n-type oxide semiconductor or a p-type oxide semiconductor.

For example, the n-type oxide semiconductor may include at least one of indium oxide (InOₓ), zinc oxide (ZnOₓ), indium tin oxide (InSnOₓ), indium zinc oxide (InZnOₓ), indium gallium oxide (InGaOₓ), zinc tin oxide (ZnSnOₓ), aluminum zinc oxide (AlZnOₓ), indium gallium zinc oxide (InGaZnOₓ), gallium zinc oxide (GaZnOₓ), indium zinc tin oxide (InZnSnOₓ), and hafnium indium zinc oxide (HfInZnOₓ), and the p-type oxide semiconductor may include at least one of copper oxide (CuOₓ), nickel oxide (NiOₓ), tin oxide (SnOₓ), manganese oxide (MnOₓ), copper aluminum oxide (CuAlOₓ), copper gallium oxide (CuGaOₓ), and copper chromium oxide (CuCrOₓ).

In some embodiments, a source/drain electrode layer (refer to 150 in FIG. 4) may be formed at both ends of the semiconductor channel layer 140. For example, the source/drain electrode layer 150 may include a source electrode layer formed at one end of the semiconductor channel layer 140 and a drain electrode layer formed at the other end of the semiconductor channel layer 140.

The control gate electrode layer 110, the inner electrode layer 130, and/or the source/drain electrode layer 150 may be formed of a conductive material such as a metal, a metal nitride, or doped polysilicon.

When driving the ferroelectric transistor 100, a control voltage may be applied to the control gate electrode 110, and no separate voltage may be applied to the inner electrode 130. Therefore, the inner electrode 130 may function as a floating electrode. By adding the inner electrode 130 to the ferroelectric transistor 100, the first ferroelectric layer 120a and the second ferroelectric layer 120b are separated, and a polarization voltage induced in the first ferroelectric layer 120a and the second ferroelectric layer 120b may be controlled.

In the ferroelectric transistor 100, a first stacked structure S1 of the control gate electrode layer 110, the first ferroelectric layer 120a, and the inner electrode layer 130 may form one capacitor structure, and a second stacked structure S2 of the inner electrode layer 130, the second ferroelectric layer 120b, and the semiconductor channel layer 140 may form the other capacitor structure. The first stacked structure S1 may have a first capacitance C1, and the second stacked structure S2 may have a second capacitance C2.

In the ferroelectric transistor 100, a first cross-sectional area A1 where the first ferroelectric layer 120a contacts with the control gate electrode 110 in the first stacked structure S1 may be same as a cross-sectional area A2 where the second ferroelectric layer 120b contacts with the inner electrode 130 in the second stacked structure S2. However, a first thickness d1 of the first ferroelectric layer 120a may be different from a second thickness d2 of the second ferroelectric layer 120b. For example, the second thickness d2 may be smaller than the first thickness d1.

The ferroelectric transistor 100 may control operating characteristics thereof by controlling a ratio of the first capacitance C1 of the first stacked structure S1 to the second capacitance C2 of the second stacked structure S2. For example, a ratio (C2/C1) of the second capacitance C2 to the first capacitance C1 may be proportional to a ratio (A2/A1) of the second cross-sectional area A2 to the first cross-sectional area A1 and inversely proportional to a ratio (d2/d1) of the second thickness d2 to the first thickness d1.

In a ferroelectric transistor 100, the ratio (A2/A1) of the second cross-sectional area A2 to the first cross-sectional area A1 is fixed to 1, and thus the ratio (C2/C1) of the second capacitance C2 to the first capacitance C1 may be controlled by adjusting the ratio (d2/d1) of the second thickness d2 to the first thickness d1 or the ratio (d1/d2) of the first thickness d1 to the second thickness d2. For example, by increasing the ratio (d1/d2) of the first thickness d1 to the second thickness d2, the ratio (C2/C1) of the second capacitance C2 to the first capacitance C1 may be increased.

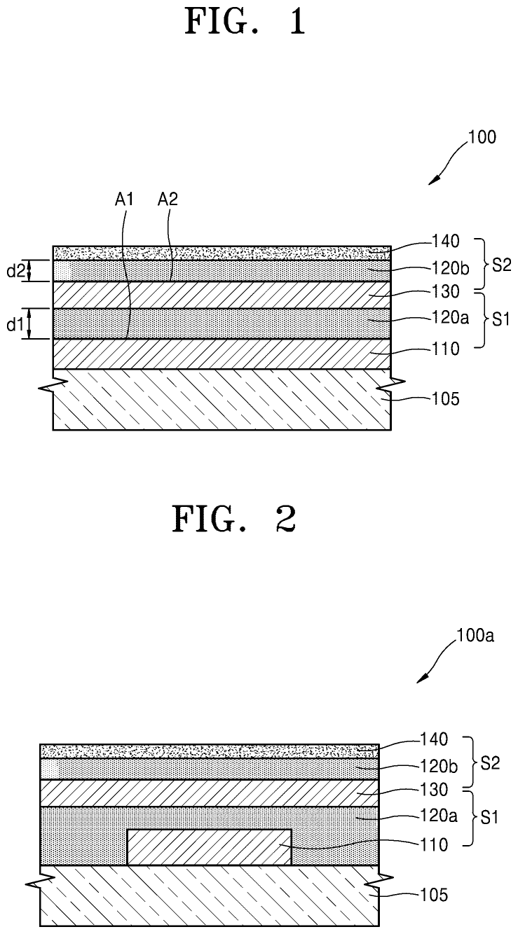

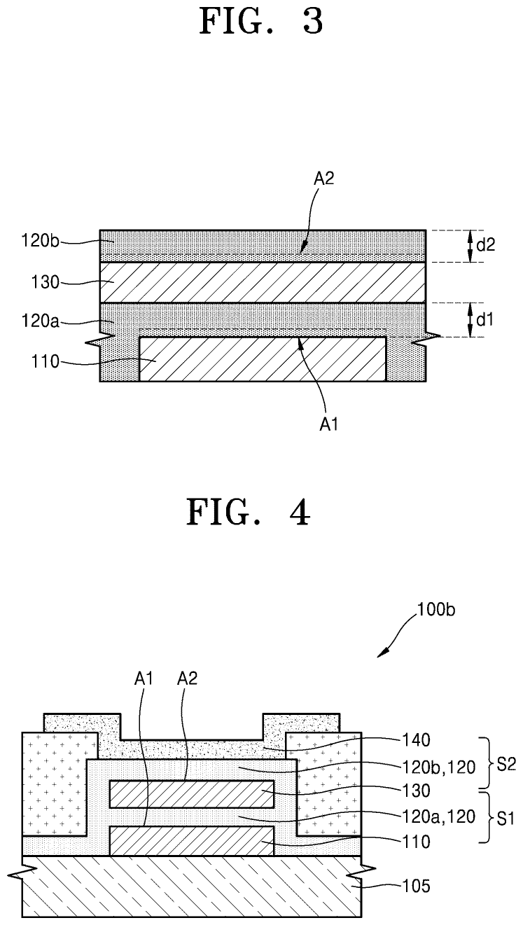

FIG. 2 is a schematic cross-sectional view showing a ferroelectric transistor 100a according to another embodiment of the present disclosure, and FIG. 3 is a schematic cross-sectional view showing a portion of the ferroelectric transistor 100a in FIG. 2. The ferroelectric transistor 100a is a partially modified configuration of the ferroelectric transistor 100 in FIG. 1, and since the embodiments may be referred to each other, duplicated descriptions will be omitted.

Referring to FIGS. 2 and 3, the control gate electrode layer 110 in the ferroelectric transistor 100a may be formed with a width narrower than that of the inner electrode layer 130. Accordingly, in the ferroelectric transistor 100a, the first cross-sectional area A1 where the first ferroelectric layer 120a contacts with the control gate electrode layer 110 in the first stacked structure S1 may be smaller than the cross-sectional area A2 where the second ferroelectric layer 120b contacts with the inner electrode layer 130 in the second stacked structure S2. Meanwhile, the first thickness d1 of the first ferroelectric layer 120a may be the same as or different from the second thickness d2 of the second ferroelectric layer 120b.

In the ferroelectric transistor 100a, when the ratio (d1/d2) of the first thickness d1 to the second thickness d2 is fixed, the ratio (A2/A1) of the second cross-sectional area A2 to the first cross-sectional area A1 may be adjusted to adjust the ratio (C2/C1) of the second capacitance C2 to the first capacitance C1. For example, by increasing the ratio (A2/A1) of the second cross-sectional area A2 to the first cross-sectional area A1, the ratio (C2/C1) of the second capacitance C2 to the first capacitance C1 may be increased.

FIG. 4 is a schematic cross-sectional view showing a ferroelectric transistor 100b according to still another embodiment of the present disclosure. The ferroelectric transistor 100b is a partially modified configuration of the ferroelectric transistor 100 in FIG. 1, and the embodiments may be referred to each other and duplicated descriptions will be omitted.

Referring to FIG. 4, in the ferroelectric transistor 100b, the first ferroelectric layer 120a and the second ferroelectric layer 120b may be connected to each other to be portions of the ferroelectric layer 120. For example, the first ferroelectric layer 120a and the second ferroelectric layer 120b may be formed of a same material, and after the first ferroelectric layer 120a is formed, the ferroelectric layer 120 may be formed by forming the second ferroelectric layer 120b to be connected to the first ferroelectric layer 120a.

In the ferroelectric transistor 100b, the ratio of the first capacitance C1 of the first stacked structure S1 to the second capacitance C2 of the second stacked structure S2 may be substantially the same as or similar to the ferroelectric transistor 100 in FIG. 1.

The source/drain electrode layer 150 may be formed at both ends of the semiconductor channel layer 140. For example, the source/drain electrode layer 150 may include the source electrode layer formed at an end of the semiconductor channel layer 140 and the drain electrode layer formed at the other end of the semiconductor channel layer 140. For example, the source/drain electrode layer 150 is first formed and patterned on the substrate, and then the semiconductor channel layer 140 is formed thereon, so that the source/drain electrode layer 150 may be disposed at both ends of the semiconductor channel layer 140. As another example, after forming the semiconductor channel layer 140, the source/drain electrode layer 150 may be formed thereon and then patterned.

A structure of the source/drain electrode layer 150 in the ferroelectric transistor 100b may be applied identically or similarly to the ferroelectric transistors 100, 100a described above.

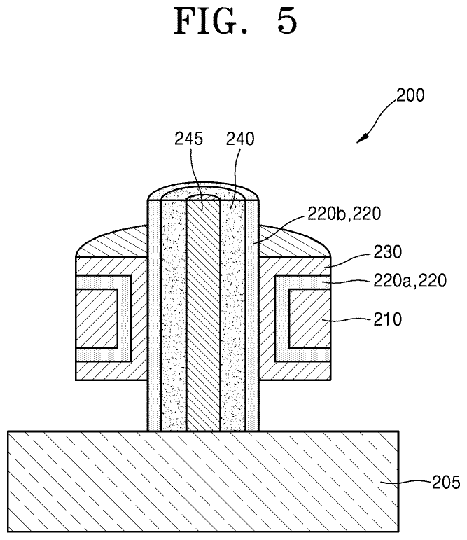

FIG. 5 is a schematic cross-sectional view showing a ferroelectric transistor 200 according to yet another embodiment of the present disclosure. The ferroelectric transistor 200 is obtained by modifying some configurations of the ferroelectric transistors 100, 100a, 100b in FIGS. 1 to 4 into a three-dimensional structure, and the corresponding configurations may be referred to each other.

Referring to FIG. 5, the ferroelectric transistor 200 may include a substrate 205, a control gate electrode layer 210, a ferroelectric layer 220, an inner electrode layer 230, and a semiconductor channel layer 240.

In the ferroelectric transistor 200, the control gate electrode layer 210 and the semiconductor channel layer 240 may be provided on the substrate 205, and the inner electrode layer 230 may be provided between the semiconductor channel layer 240 and the control gate electrode layer 210. The ferroelectric layer 220 may include an outer ferroelectric layer 220a and an inner ferroelectric layer 220b.

More specifically, the semiconductor channel layer 240 may be disposed in a cylindrical shape extended vertically on the substrate 205. The inner ferroelectric layer 220b may be disposed on an outer circumferential surface of the semiconductor channel layer 240, the inner electrode layer 230 may be disposed on an outer circumferential surface of the inner ferroelectric layer 220b, the outer ferroelectric layer 220a may be disposed on an outer circumferential surface of the inner electrode layer 230, and the control gate electrode layer 210 may be disposed on an outer circumferential surface of the outer ferroelectric layer 220a.

For example, the inner ferroelectric layer 220b may be disposed to surround the outer circumferential surface of the semiconductor channel layer 240 once, the inner electrode layer 230 may be disposed to surround the outer circumferential surface of the inner ferroelectric layer 220b once, the outer ferroelectric layer 220a may be disposed to surround the outer circumferential surface of the inner electrode layer 230 once, and the control gate electrode layer 210 may be disposed to surround the outer circumferential surface of the outer ferroelectric layer 220a once. Accordingly, the outer ferroelectric layer 220a may be interposed between the control gate electrode layer 210 and the inner electrode layer 230, and the inner ferroelectric layer 220b may be interposed between the inner electrode layer 230 and the semiconductor channel layer 240.

In some embodiments, the inner electrode layer 230 may have a cylindrical shape with a circumferential groove recessed outward. The outer ferroelectric layer 220a may be formed inside the groove of the inner electrode layer 230, and the control gate electrode layer 210 may be formed outside of the outer ferroelectric layer 220a to fill the groove of the inner electrode layer 230.

In some embodiments, an interior of the cylindrical structure of the semiconductor channel layer 240 may be filled with a filler 245. For example, the filler 245 may include an insulating material.

In the ferroelectric transistor 200, materials and functions of the control gate electrode layer 210, the ferroelectric layer 220, the inner electrode layer 230, and the semiconductor channel layer 240 may be referred to the descriptions of the control gate electrode layer 110, the ferroelectric layer 120, the inner electrode layer 130, and the semiconductor channel layer 140 in the ferroelectric transistors 100, 100a, 100b described above. Furthermore, the outer ferroelectric layer 220a may correspond to the first ferroelectric layer 120a in FIGS. 1 to 4, and the inner ferroelectric layer 220b may correspond to the second ferroelectric layer 120b in FIGS. 1 to 4.

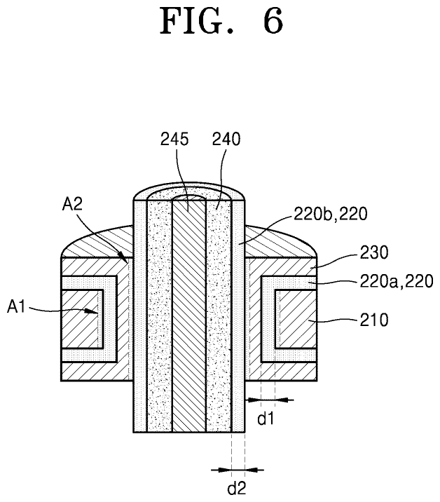

Although FIG. 6 shows that one unit cell of the ferroelectric transistor 200 is included, such a unit cell may be vertically stacked in multi-layer.

In the ferroelectric transistor 200, a first stacked structure S1 of the control gate electrode layer 210, the outer ferroelectric layer 220a, and the inner electrode layer 230 may form one capacitor structure, and a second stacked structure S2 of the inner electrode layer 230, the inner ferroelectric layer 220b, and the semiconductor channel layer 240 may form the other capacitor structure. The first stacked structure S1 may have a first capacitance C1, and the second stacked structure S2 may have a second capacitance C2.

In the ferroelectric transistor 200, a first cross-sectional area A1 where the outer ferroelectric layer 220a contacts with the control gate electrode layer 210 in the first stacked structure S1 may be smaller than a cross-sectional area A2 where the inner ferroelectric layer 220b contacts with the inner electrode layer 230 in the second stacked structure S2.

Meanwhile, a first thickness d1 of the outer ferroelectric layer 220a may be the same as or different from a second thickness d2 of the inner ferroelectric layer 220b.

The ferroelectric transistor 200 may control operating characteristics thereof by controlling a ratio of the first capacitance C1 of the first stacked structure S1 to the second capacitance C2 of the second stacked structure S2. For example, a ratio (C2/C1) of the second capacitance C2 to the first capacitance C1 may be proportional to a ratio (A2/A1) of the second cross-sectional area A2 to the first cross-sectional area A1 and inversely proportional to a ratio (d2/d1) of the second thickness d2 to the first thickness d1. For example, in order to adjust the ratio (C2/C1) of the second capacitance C2 to the first capacitance C1, a thickness of the inner ferroelectric layer 220b may be adjusted.

In some embodiments, in the ferroelectric transistor 200, the capacitance ratio (C2/C1) and a memory window may be adjusted by changing the thickness of the inner ferroelectric layer 220b while maintaining the other configuration. For example, as the thickness of the inner ferroelectric layer 220b is decreased, the capacitance ratio (C2/C1) and the memory window may be increased.

The above-mentioned ferroelectric transistors 100, 100a, 100b, 200 may control the ratio (C2/C1) of the second capacitance C2 of the second stacked structure S2 to the first capacitance C1 of the first stacked structure S1 in order to control operating characteristics thereof.

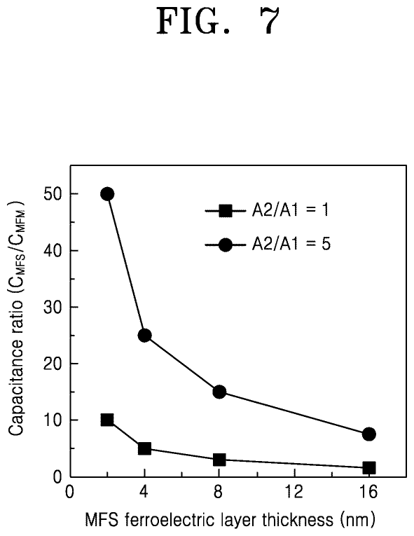

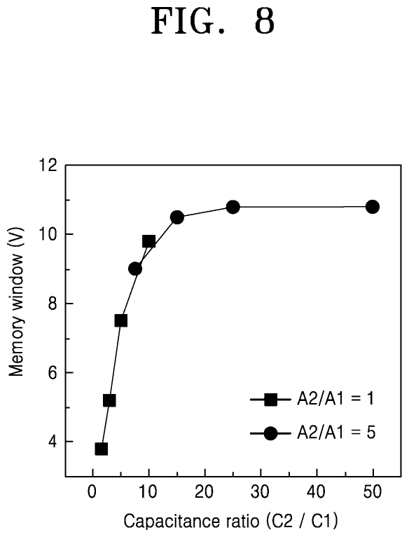

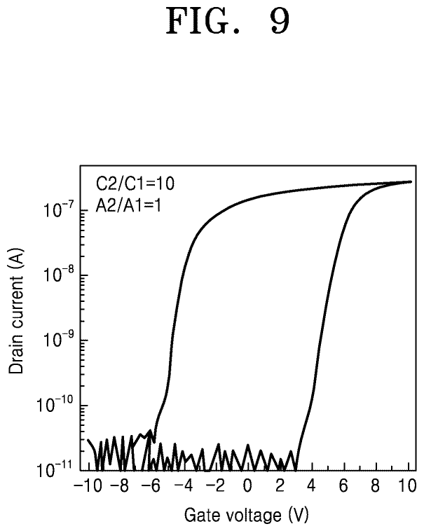

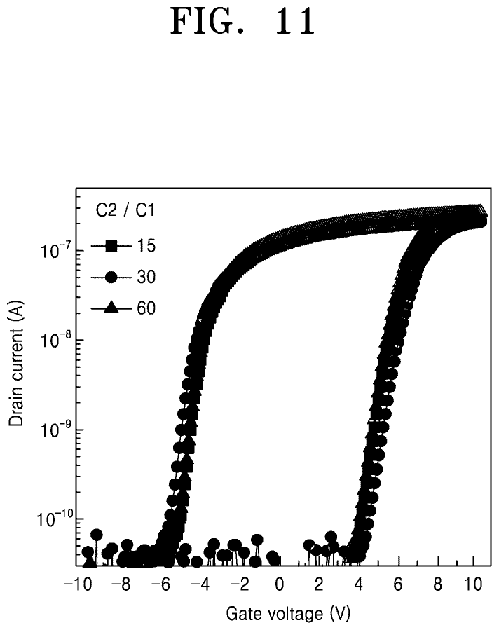

Hereinafter, a method for controlling the capacitance ratio (C2/C1) and the operating characteristics thereof will be described. Hereinafter, although FIGS. 7 to 11 illustrate experimental results of the ferroelectric transistors 100, 100a, 100b, the same results are confirmed for the ferroelectric transistor 200, and thus the following experimental results may be applied to the ferroelectric transistors 100, 100a, 100b, 200 as a whole.

Referring to FIG. 7, it may be seen that in the ferroelectric transistors 100, 100a, 100b, 200, as the thickness of the second ferroelectric layer 120b in the second structure S2 increases, the capacitance ratio (C2/C1) decreases abruptly. In particular, it may be seen that as the area ratio (A2/A1) increases, the decrease in the capacitance ratio (C2/C1) due to the increase in the thickness of the second ferroelectric layer 120b is greater. Therefore, it may be seen that when the thickness of the second ferroelectric layer 120b is adjusted while the area ratio (A2/A1) is increased, the capacitance ratio (C2/C1) may be significantly changed.

Referring to FIGS. 8 to 11, it may be seen that in the ferroelectric transistors 100, 100a, 100b, 200, as the capacitance ratio (C2/C1) increases, the memory window of the ferroelectric transistor increases, and when the memory window exceeds a certain level, it is saturated.

Further, when the area ratio (A2/A1) is 1, for example, in a case of the ferroelectric transistors 100, 100b, it may be seen that the memory window changes in a range of 4 to 10 V by changing the capacitance ratio (C2/C1) from 1 to 10. Therefore, when the area ratio (A2/A1) is 1, in order to increase the memory window, it is necessary to adjust a thickness ratio (d1/d2) as large as possible to increase the capacitance ratio (C2/C1).

In addition, when the area ratio (A2/A1) is 5, for example, in a case of a modified example of ferroelectric transistors 100a, it may be seen that the memory window changes in a range of 9 to 11 V by changing the capacitance ratio (C2/C1) from 6 to 50. An upper limit of the capacitance ratio (C2/C1) is not significantly limited, but may be set to 50 to 60 in consideration of a structural limitation and a manufacturing process. Therefore, when the area ratio (A2/A1) is 5 or more, the memory window may be maintained at equal to or greater than 8 V without significantly depending on the thickness ratio (d1/d2). This is because when the area ratio (A2/A1) is 5 or more, the memory window is saturated even when the capacitance ratio (C2/C1) is only slightly increased.

Therefore, in a change tendency of the memory window according to the capacitance ratio (C2/C1) described above, in order to make the memory window of the ferroelectric transistor equal to or greater than 6 V, the capacitance ratio (C2/C1) of the ferroelectric transistor may be controlled to at least 5 or more, for example, in a range of 5 to 50. Further, in order to make the memory window of the ferroelectric transistor equal to or greater than 7 V, the capacitance ratio (C2/C1) of the ferroelectric transistor may be controlled to at least 6 or more, for example, in a range of 6 to 50. Furthermore, in order to make the memory window of the ferroelectric transistor equal to or greater than 10 V, the capacitance ratio (C2/C1) of the ferroelectric transistor may be controlled to at least 10 or more, for example, in a range of 10 to 50.

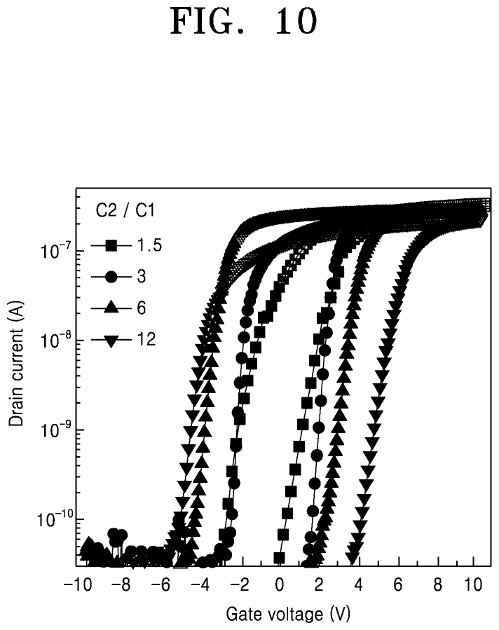

In addition, as shown in FIG. 10, when the area ratio (A2/A1) is 1, it may be seen that the capacitance ratio (C2/C1) and the memory window change significantly depending on the thickness of the second ferroelectric layer 120b. Accordingly, it may be seen that when the capacitance ratio (C2/C1) is about 6 or more, that is, when the thickness ratio (d1/d2) is about 6 or more, the memory window of about equal to or greater than 7 V may be secured. Therefore, when the area ratio (A2/A1) is 1 and the thickness ratio (d1/d2) is set to about 6 or more, the memory window of about equal to or greater than 7 V may be secured.

Therefore, in the ferroelectric transistors 100, 100a, 100b, 200 according to the embodiments of the present disclosure, the memory window of a predetermined voltage or more may be secured by appropriately adjusting the capacitance ratio (C2/C1). As such, when increasing the memory window, an operation reliability of the ferroelectric transistors 100, 100a, 100b, 200 may be improved, and a high-order multi-level operation may be implemented.

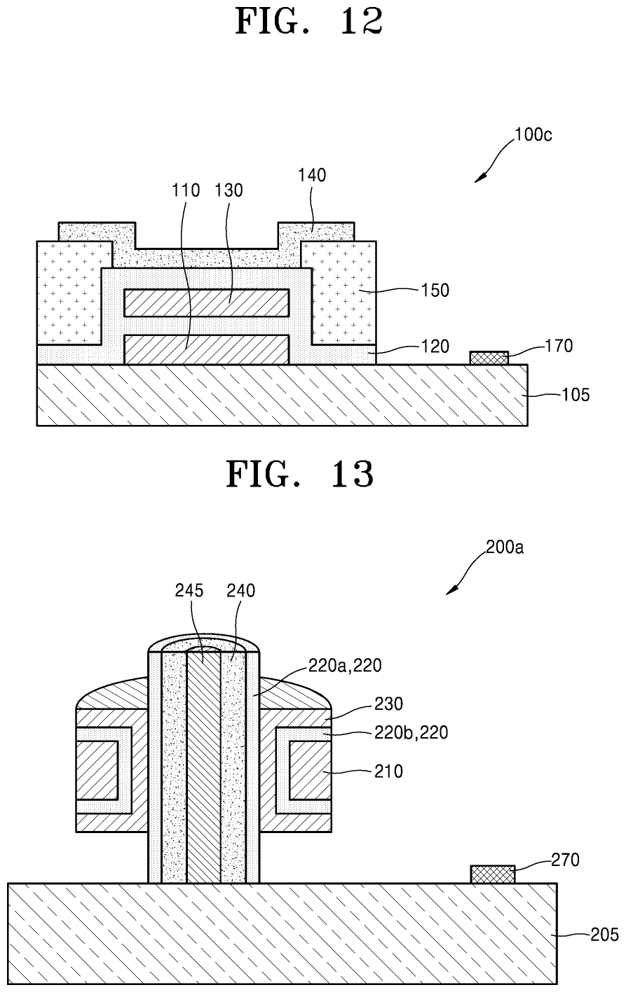

FIG. 12 is a schematic cross-sectional view showing a ferroelectric transistor 100c according to some embodiments of the present disclosure. The ferroelectric transistor 100c is a partially modified or added configuration of the above-mentioned ferroelectric transistors 100, 100a, 100b, and the embodiments may be referred to each other and duplicated descriptions will be omitted.

Referring to FIG. 12, the ferroelectric transistor 100c may include a substrate 105, a control gate electrode layer 110, a ferroelectric layer 120, an inner electrode layer 130, a semiconductor channel layer 140, and a current control device 170.

The current control device 170 may be connected to the inner electrode layer 130. In the ferroelectric transistor 100c, the current control device 170 may be used in a program operation through a displacement current control (DCC) method. For example, the multi-level operation may be possible by controlling a polarization level of the ferroelectric layer 120 as multi-level by controlling a displacement current through the inner electrode layer 130 using the current control device 170.

In some embodiments, the current control device 170 may be formed in the substrate 105 or on the substrate 105. For example, the current control device 170 may include various devices capable of adjusting an amount of current flowing and may include, for example, a bipolar junction transistor (BJT). For example, the bipolar junction transistor (BJT) may be formed in a junction structure by injecting a P-type impurity and an N-type impurity into a semiconductor layer of the substrate 105.

Therefore, the current control device 170 may be integrated into the ferroelectric transistor 100c. As another example, the current control device 170 may use an n-type or a p-type field effect transistor. In a case of the n-type or the p-type field effect transistor (FET), in controlling of the displacement current, the displacement current through the inner electrode layer 130 may be controlled by changing a voltage applied to a gate.

FIG. 13 is a schematic cross-sectional view showing a ferroelectric transistor 200a according to some embodiments of the present disclosure. The ferroelectric transistor 200a is a partially modified configuration of the ferroelectric transistors 100c, 200, and corresponding configurations may be referred to each other.

Referring to FIG. 13, the ferroelectric transistor 200a may include a substrate 205, a control gate electrode layer 210, a ferroelectric layer 220, an inner electrode layer 230, a semiconductor channel layer 240, and a current control device 270.

The current control device 270 may be connected to the inner electrode layer 230. In the ferroelectric transistor 200a, the current control device 270 may be used in the program operation through the displacement current control (DCC) method. For example, the multi-level operation may be possible by controlling a polarization level of the ferroelectric layer 220 as multi-level by controlling the displacement current through the inner electrode layer 230 using the current control device 270.

Hereinafter, an operation of the ferroelectric transistor 100c and the ferroelectric transistor 200a will be described.

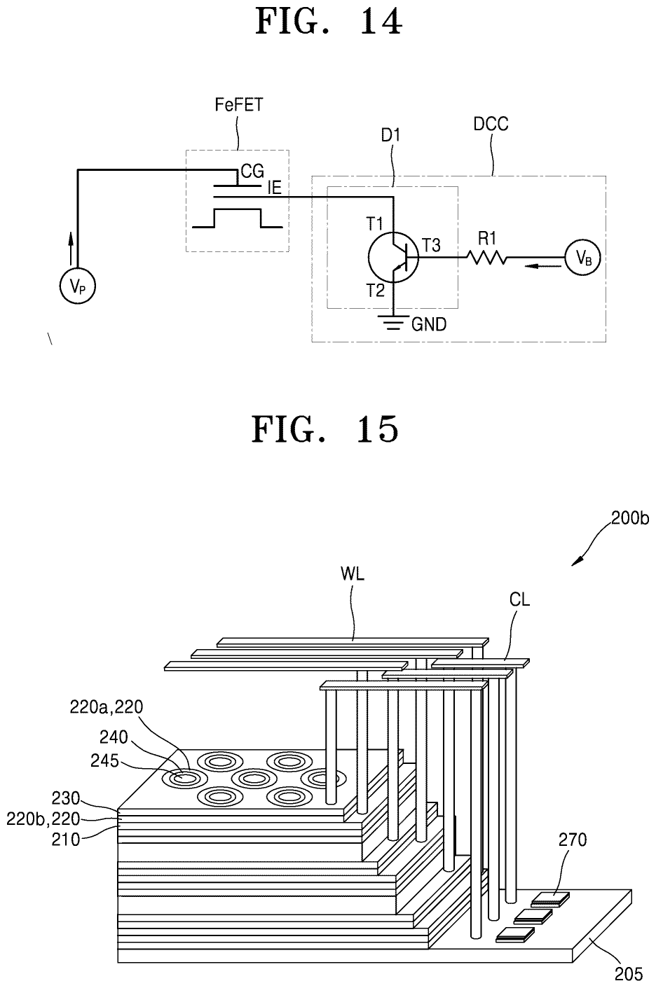

FIG. 14 is an equivalent circuit diagram of ferroelectric memory devices 100c, 200a in FIGS. 12 and 13.

Referring to FIG. 14, the ferroelectric memory devices 100c, 200a may be understood to include a ferroelectric transistor (FeFET) and a displacement current controller (DCC).

The ferroelectric transistor (FeFET) may include an inner terminal (IE) and a control gate terminal (CG). The inner terminal (IE) and the control gate terminal (CG) may be connected to the inner gate electrode layers 130, 230 and the control gate electrode layers 110, 210 of the ferroelectric memory devices 100c, 200a, respectively. The ferroelectric transistor (FeFET) may indicate a stacked structure of the ferroelectric memory devices 100, 200 to the control gate electrode layers 110, 210 of the semiconductor channel layers 110, 210.

The displacement current controller (DCC) may include a current control device D1. The current control device D1 may correspond to the current control devices 170, 270 of the ferroelectric memory devices 100c, 200a. Furthermore, the displacement current controller (DCC) may further include a base power supply unit (VB) connected to the current control device D1 through a resistor R1.

For example, the current control device D1 may include a bipolar junction transistor (BJT) that includes a collector terminal T1, an emitter terminal T2, and a base terminal T3. The base terminal T3 may be connected to the base power supply unit (VB) through the resistor R1, the collector terminal T1 may be connected to an inner terminal (IE) of the ferroelectric transistor (FeFET), and the emitter terminal T2 may be connected to the ground (GND).

When a program voltage is applied from a program power supply unit (VP) to the control gate terminal (CG), the polarization phenomenon may be induced in the ferroelectric transistor (FeFET), that is, the ferroelectric layers 120, 220 of the ferroelectric memory devices 100c, 200a. At the same time or later, the displacement current through the inner terminal (IE) may be controlled through the displacement current controller (DCC).

For example, by changing a current flowing into the base terminal T3 of the bipolar junction transistor (BJT), the displacement current through the ferroelectric transistor (FeFET), that is, the inner electrode layers 130, 230 in the ferroelectric memory devices 100c, 200a may be controlled. More specifically, the change in the current flowing into the base terminal T3 may be performed by changing an applied voltage of the base power supply unit (VB).

Accordingly, the polarization level in the ferroelectric layers 120, 220 may be controlled as multi-level by controlling the displacement current through the inner electrode layers 130, 230 of the ferroelectric memory devices 100c, 200a. The displacement current may induce partial polarization in the ferroelectric layers 120, 220 and accordingly, the multi-level of the displacement current may induce multi-level polarization in the ferroelectric layers 120, 220. As the displacement current is increased, a threshold voltage of the ferroelectric memory devices 100c, 200a may change significantly. For example, as the displacement current in the program operation increases, the threshold voltage of the ferroelectric memory devices 100c, 200a may decrease. Therefore, when the displacement current is controlled as multi-level, the ferroelectric memory devices 100c, 200a may have a threshold voltage of multi-level, and thus they may operate as multi-level.

FIG. 15 is a schematic perspective view showing a ferroelectric memory device 200b according to some embodiments of the present disclosure. The ferroelectric memory device 200b is enlarged or modified from a partial configuration of the ferroelectric transistor 200a in FIG. 13, and the two embodiments may be referred to each other and duplicated descriptions will be omitted.

Referring to FIG. 15, the ferroelectric memory device 200b may be formed on the substrate 205 in a three-dimensional (3D) structure.

More specifically, a plurality of semiconductor channel layers 240 may be arranged vertically on the substrate 205. A plurality of the ferroelectric layers 220 may be disposed on an outer circumferential surface of the semiconductor channel layers 240 and may be separated in a multi-layer structure along a vertical extension direction of the semiconductor channel layers 240 and disposed to be spaced apart from each other. Between the ferroelectric layers 220 disposed to be spaced apart in the vertical direction, the isolation-insulating layers 260 may be disposed on the outer circumferential surface of the semiconductor channel layers 240.

A plurality of control gate electrode layers 210 may be disposed in a multi-layer structure outside the ferroelectric layers 220 along the vertical extension direction of the semiconductor channel layers 240. A plurality of the inner electrode layers 230 may be provided between the semiconductor channel layers 240 and control gate electrode layers 210, respectively.

The plurality of ferroelectric layers 220 may include an inner ferroelectric layer 220b surrounding the outer circumferential surface of the semiconductor channel layer 240 and an outer ferroelectric layer 220a between the control gate electrode layer 210 and the inner electrode layer 230, respectively.

A plurality of the current control devices 270 may be formed to be connected to the inner electrode layers 230 in the substrate 205 or on the substrate 205.

The control gate electrode layers 210 and the multi-layer structure of the inner electrode layers 230 on the substrate 205 may have a step structure at an end portion for contact connection. Word lines (WL) may be connected to the multi-layered control gate electrode layers 210 exposed in the step structure, respectively. Current control lines (CL) may be connected to the multi-layered inner electrode layers 230 exposed in the step structure, respectively.

Therefore, the ferroelectric memory device 200b may be formed in a three-dimensional monolithic structure using a ferroelectric transistor structure, the current control devices 270, and the substrate 205. In the ferroelectric memory device 200b, a number of arrays of a memory cell, for example, a number of the semiconductor channel layers 240 or a number of layers of the control gate electrode layer 210 is shown as an example and may be appropriately increased or decreased according to a memory capacity.

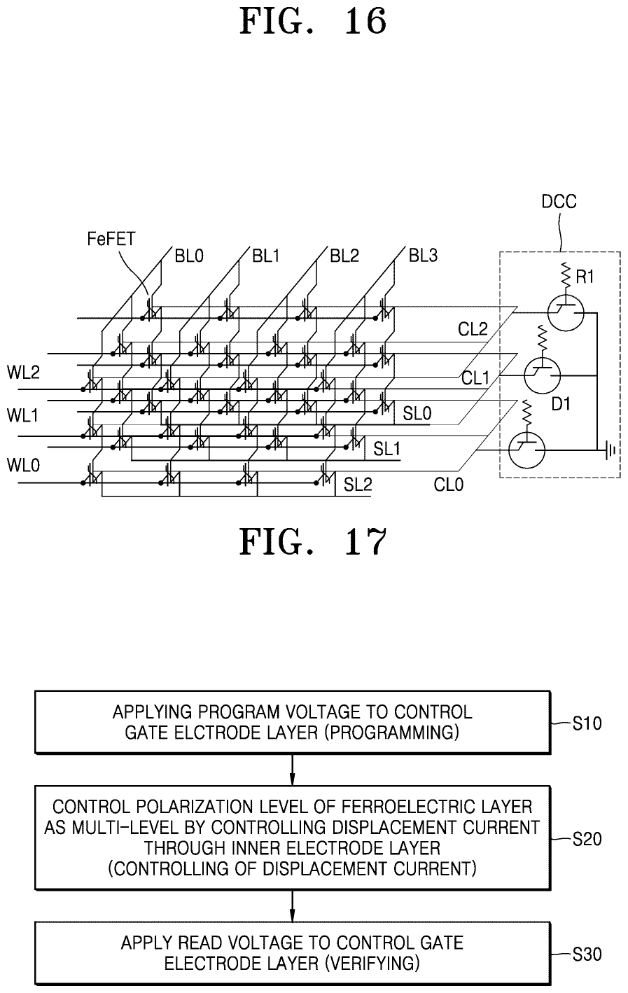

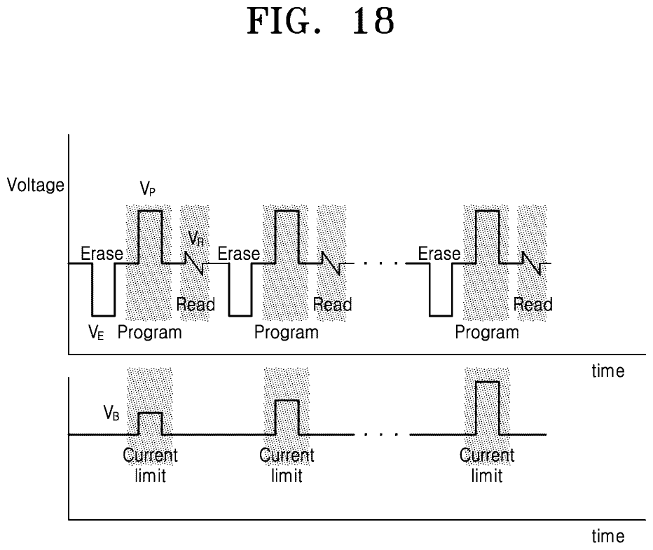

FIG. 16 is an equivalent circuit diagram of the ferroelectric memory device 200b in FIG. 15.

Referring to FIG. 16, the ferroelectric memory device 200b may be understood to include the ferroelectric transistor (FeFET) and the displacement current controller (DCC).

A plurality of word lines (WL0, WL1, WL2) may be connected to the ferroelectric transistor (FeFET), that is, the control gate electrode layers 210 of the ferroelectric memory device 200a. A plurality of bit lines (BL0, BL1, BL2, BL3) may be connected to one end of the semiconductor channel layers 240, and a plurality of source lines (SL0, SL1, SL2) may be connected to the other end of the semiconductor channel layers 240. A plurality of current control lines (CL0, CL1, CL2) may be connected to the inner electrode layers 230.

Hereinafter, an operating method of the ferroelectric memory devices 100c, 200a, 200b described above will be described in more detail.

FIG. 17 is a flowchart showing a multi-level operating method of a ferroelectric memory device according to some embodiments of the present disclosure, and FIG. 18 is a time chart showing a multi-level operating method of a ferroelectric memory device according to some embodiments of the present disclosure.

Referring to FIGS. 17 and 18, programming (S10) of applying the program voltage (Vp) to the control gate electrode layers 110, 210 may be performed. For example, in the programming (S10), the program voltage may be applied from the program power supply unit (VP) to the control gate terminal (CG) as shown in FIG. 14. Optionally, as shown in FIG. 18, erasing of applying an erase voltage (VE) to the control gate electrode layers 110, 210 may be performed before the programming (S10).

Then, controlling of the displacement current (S20) may be performed to control the polarization level of the ferroelectric layers 120, 220 as multi-level by controlling the displacement current through the inner electrode layers 130, 230. For example, in the controlling of the displacement current (S20), the displacement current through the inner electrode layers 130, 230 may be controlled through the current control devices 170, 270. In the controlling of the displacement current (S20), as the displacement current is increased, the threshold voltage of the ferroelectric memory devices 100c, 200a, 200b may be decreased. In FIG. 18, the displacement current is indicated as current limit.

In some embodiments, in the controlling of the displacement current (S20), as shown in FIG. 14, by changing the current flowing into the base terminal T3 of the bipolar junction transistor (BJT), the displacement current through the inner electrode layers 130, 230 may be controlled, and further, the change in the current flowing into the base terminal T3 may be performed by changing the applied voltage of the base power supply unit (VB).

Then, verifying (S30) of applying a read voltage to the control gate electrode layers 110, 210 may be performed. In the verifying (S30), whether the polarization level of the ferroelectric layers 120, 220 is at a desired level, that is, whether the threshold voltage of the ferroelectric memory devices 100c, 200a, 200b has reached the desired level may be confirmed.

In some embodiments, when the polarization level of the ferroelectric layers 120, 220 is not at the desired level, the programming (S10), the controlling of the displacement current (S20), and the verifying (S30) described above may be repeated multiple times while changing the displacement current to change the polarization level of the ferroelectric layers 120, 220. For example, a change in the displacement current may be performed by adjusting a voltage level of the base power supply unit (VB).

In some embodiments, as shown in FIG. 18, the erasing of applying the erase voltage (VE) to the control gate electrode layers 110, 210 may be performed before repeating the programming (S10) after the verifying (S30). Accordingly, unlike an incremental step pulse programming (ISPP) method that increases a voltage cumulatively, in the present embodiments, the multi-level operation may be implemented by controlling the displacement current after the program voltage (Vp) is applied once.

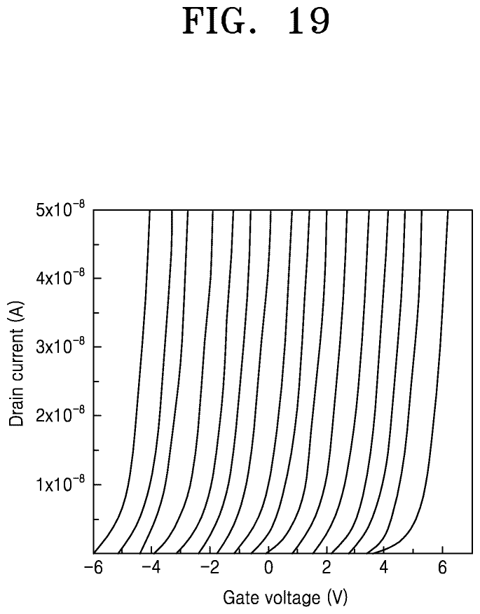

FIGS. 19 to 21 are graphs showing multi-level operation characteristics of a ferroelectric memory device according to some embodiments of the present disclosure.

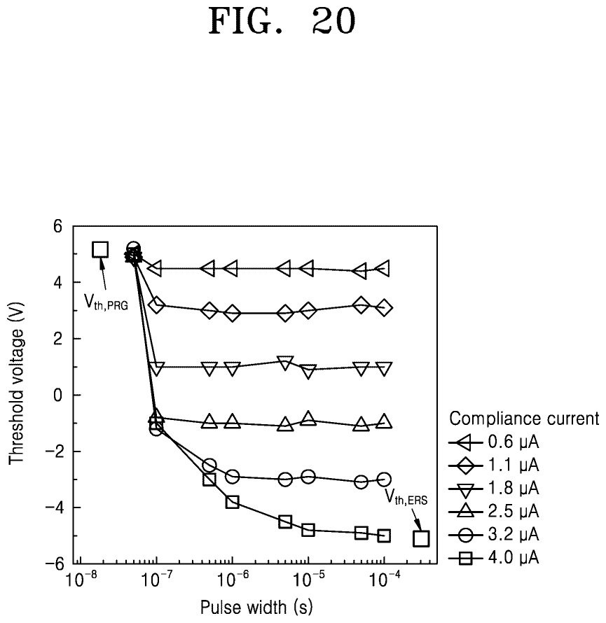

Referring to FIGS. 19 to 21, it may be seen that the threshold voltage is changed into multi-level through the displacement current control (DCC) method according to the embodiments in the ferroelectric memory devices 100c, 200a, 200b. Furthermore, it may be seen that as the displacement current increases, the threshold voltage decreases. In FIG. 20, the displacement current is indicated as compliance current.

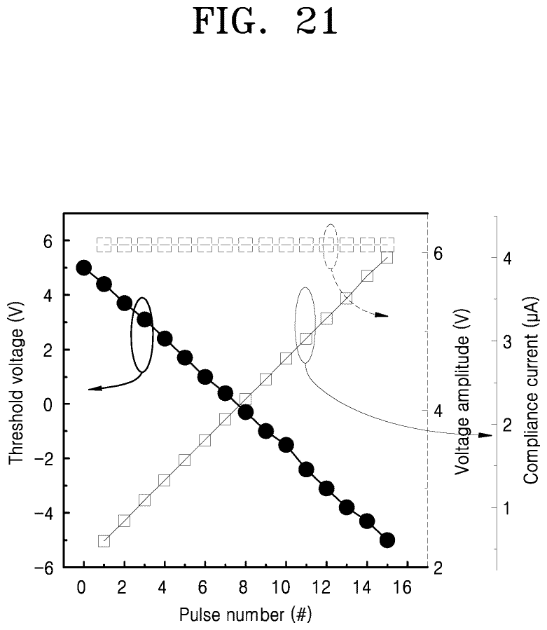

In addition, as shown in FIG. 21, it may be seen that a linear threshold voltage change, that is, a linear multi-level operation, may be implemented through the displacement current control (DCC) according to the present embodiments.

Therefore, it may be seen that the linear multi-level operation may be implemented by using the structure and the operating method of the ferroelectric memory devices 100c, 200a, 200b according to the embodiments of the present disclosure.

The present disclosure has been described with reference to the embodiments shown in the drawings, but these embodiments are merely illustrative and it should be understood by a person with ordinary skill in the art that various modifications and equivalent embodiments can be made without departing from the scope of the present disclosure. Therefore, the true technical protective scope of the present disclosure should be determined based on the technical concept of the appended claims.

What is claimed is:

1. A ferroelectric transistor comprising:
a substrate;
a control gate electrode layer on the substrate;
a first ferroelectric layer on the control gate electrode layer;
an inner electrode layer on the first ferroelectric layer;
a second ferroelectric layer on the inner electrode layer; and
a semiconductor channel layer on the second ferroelectric layer,
wherein a ratio of a second capacitance of a second stacked structure of the inner electrode layer, the second ferroelectric layer, and the semiconductor channel layer to a first capacitance of a first stacked structure of the control gate electrode layer, the first ferroelectric layer, and the inner electrode layer is 5 or more.

2. The ferroelectric transistor of claim 1,
wherein, in order to have a memory window equal to or greater than 7 V, the ratio of the second capacitance to the first capacitance is 6 or more.

3. The ferroelectric transistor of claim 1,
wherein, in order to have a memory window equal to or greater than 10 V, the ratio of the second capacitance to the first capacitance is 10 or more.

4. The ferroelectric transistor of claim 1,
wherein a ratio of a second area where an upper surface of the inner electrode layer contacts with the second ferroelectric layer in the second stacked structure to a first area where an upper surface of the control gate electrode layer contacts with the first ferroelectric layer in the first stacked structure is 1, and
in order to have a memory window equal to or greater than 7 V, a ratio of a first thickness of the first ferroelectric layer to a second thickness of the second ferroelectric layer is 6 or more.

5. The ferroelectric transistor of claim 1,
wherein, in order to have a memory window equal to or greater than 8 V, a ratio of a second area where an upper surface of the inner electrode layer contacts with the second ferroelectric layer in the second stacked structure to a first area where an upper surface of the control gate electrode layer contacts with the first ferroelectric layer in the first stacked structure is 5 or more.

6. The ferroelectric transistor of claim 1,
wherein the first ferroelectric layer and the second ferroelectric layer are formed of a same material.

7. A ferroelectric transistor comprising:
a substrate;
a semiconductor channel layer having a cylindrical shape extended vertically on the substrate;
an inner ferroelectric layer surrounding an outer circumferential surface of the semiconductor channel layer once;
an inner electrode layer surrounding an outer circumferential surface of the inner ferroelectric layer once;
an outer ferroelectric layer surrounding an outer circumferential surface of the inner electrode layer once; and
a control gate electrode layer surrounding an outer circumferential surface of the outer ferroelectric layer once,
wherein a ratio of a second capacitance of a second stacked structure of the inner electrode layer, the inner ferroelectric layer, and the semiconductor channel layer to a first capacitance of a first stacked structure of the control gate electrode layer, the outer ferroelectric layer, and the inner electrode layer is 5 or more.

8. The ferroelectric transistor of claim 7,
wherein, in order to have a memory window equal to or greater than 7 V, the ratio of the second capacitance to the first capacitance is 6 or more.

9. The ferroelectric transistor of claim 7,
wherein, in order to adjust the ratio of the second capacitance to the first capacitance, a thickness of the inner ferroelectric layer is adjusted.

10. The ferroelectric transistor of claim 7,
wherein the inner electrode layer has a cylindrical shape with a circumferential groove recessed outward,
the outer ferroelectric layer is formed inside the groove of the inner electrode layer, and
the control gate electrode layer is formed outside of the outer ferroelectric layer to fill the groove.

11. The ferroelectric transistor of claim 1, comprising
a current control device connected to the inner electrode layer,
wherein a multi-level operation is possible by controlling a displacement current through the inner electrode layer using the current control device by controlling a polarization level of the ferroelectric layer as multi-level.

12. The ferroelectric transistor of claim 11,
wherein the current control device includes a bipolar junction transistor, and
controls the displacement current through the inner electrode layer by changing a current flowing into a base terminal of the bipolar junction transistor.

13. The ferroelectric transistor of claim 11,
wherein the base terminal is connected to a base power supply unit through a resistor, and
a change in a current flowing into the base terminal is performed by changing an applied voltage of the base power supply unit.

14. A multi-level operating method of a ferroelectric transistor including a semiconductor channel layer, a control gate electrode layer, an inner electrode layer between the semiconductor channel layer and the control gate electrode layer, and a ferroelectric layer at least interposed between the control gate electrode layer and the inner electrode layer, the method comprising:
programming of applying a program voltage to the control gate electrode layer;
controlling of a displacement current of controlling a polarization level of the ferroelectric layer as multi-level by controlling the displacement current through the inner electrode layer; and
verifying of applying a read voltage to the control gate electrode layer.

15. The method of claim 14,
wherein, in the controlling of the displacement current, as the displacement current is increased, a threshold voltage of a ferroelectric memory device is decreased.

16. The method of claim 14,
wherein the ferroelectric memory device includes a current control device connected between the inner electrode and a ground, and
controls the displacement current through the inner electrode layer using the current control device.

17. The method of claim 16,
wherein the current control device includes a bipolar junction transistor, and
controls the displacement current through the inner electrode layer by changing a current flowing into a base terminal of the bipolar junction transistor in the controlling of the displacement current.

18. The method of claim 17,
wherein the base terminal is connected to a base power supply unit through a resistor, and
a change in a current flowing into the base terminal is performed by changing an applied voltage of the base power supply unit in the controlling of the displacement current.

19. The method of claim 14,
wherein the programming, the controlling of the displacement current, and the verifying are repeated multiple times while changing the displacement current so as to change the polarization level of the ferroelectric layer.

20. The method of claim 19,
wherein erasing of applying an erase voltage to the control gate electrode layer is performed before repeating the programming after the verifying.
